(19) United States
(12) Patent Application Publication
(10) Pub. No.: US 2018/0026013 A1
(43) Pub. Date: Jan. 25, 2018

(54) MEMORY DEVICE INCLUDING INTERPOSER AND SYSTEM-IN-PACKAGE INCLUDING THE SAME

(71) Applicants: Won-Joo YUN, Yongin-si (KR); Sukyong Kang, Hwaseong-si (KR); Hye-Seung Yu, Goyang-si (KR); Hyunui Lee, Osan-si (KR)

(72) Inventors: Won-Joo YUN, Yongin-si (KR); Sukyong Kang, Hwaseong-si (KR); Hye-Seung Yu, Goyang-si (KR); Hyunui Lee, Osan-si (KR)

(21) Appl. No.: 15/612,296

(22) Filed: Jun. 2, 2017

(30) Foreign Application Priority Data
Jul. 22, 2016 (KR) 10-2016-0093618

(51) Int. Cl. H01L 25/065; H01L 23/00; H01L 21/66; H01L 23/498

(52) U.S. Cl. CPC H01L 25/0657; H01L 23/49838; H01L 24/09; H01L 24/17; H01L 22/32; H01L 2225/06541; H01L 2225/06517; H01L 2225/06513; H01L 2224/0401; H01L 2224/14131

(57) ABSTRACT

A memory device including an interposer including a first plurality of paths and a second plurality of paths, a first memory die attached to a first surface of the interposer, the first memory die including a first physical layer connected to the first plurality of paths, the first physical layer being attached to a first surface of the interposer, and a second memory die attached to a second surface of the interposer, the second memory die including a second physical layer connected to the second plurality of paths, the second physical layer being attached to a second surface of the interposer, the second physical layer not interfering with the first physical layer in a plan view may be provided.

### CROSS-REFERENCE TO RELATED APPLICATIONS

This application claims priority under 35 U.S.C. §119 to Korean Patent Application No. 10-2016-0093618, filed Jul. 22, 2016, in the Korean Intellectual Property Office, the entire contents of which are hereby incorporated by reference.

### BACKGROUND

The inventive concepts relate to memory devices, more particularly to memory devices including a memory die attached to an interposer, and/or system-in-packages (SIPS) including same.

In a computer system according to the related art, a processor and a memory are manufactured as separate packages and are attached to a printed circuit board (PCB). In general, the speed of the memory is slower than the speed of the processor. Accordingly, the speed of the memory may be improved by increasing the number of data transmission paths arranged between the memory and the processor. However, there is a spatial restriction in increasing the number of data transmission lines on the PCB.

An interposer may be used in the computer system to increase the number of the data transmission lines. The interposer may provide several hundreds of or several thousands of data transmission lines between the processor and the memory. Further, in order to reduce the distance between the processor and the memory, the processor and the memory may be arranged in one package together. The above-mentioned package may be referred to as a system-in-package (SIP).

Due to the rapid enhancement of the performance of the electronic device and the expansion of usages of the electronic device, the system-in-package may include a plurality of memories. As the number of the plurality of memories increases, the performance of the system-in-package may be further improved.

### SUMMARY

Example embodiments of the inventive concepts provide memory devices including a memory die attached to an interposer, and-'or a system-in-package including the same.

In accordance with an aspect of the inventive concepts, a memory device includes an interposer including a first plurality of paths and a second plurality of paths, a first memory die attached to a first surface of the interposer, the first memory die including a first physical layer connected to the first plurality of paths, the first physical layer being attached to a first surface of the interposer, and a second memory die attached to a second surface of the interposer, the second memory die including a second physical layer connected to the second plurality of paths, the second physical layer being attached to a second surface of the interposer, the second physical layer not interfering with the first physical layer in a plan view.

In accordance with another embodiment of the inventive concepts, a system-in-package includes a processor, an interposer connected to the processor, a first memory die attached to a first surface of the interposer, the first memory die including a first physical layer, the first physical layer configured to perform input and output of data to and from the processor, and a second memory die attached to a second surface of the interposer, the second memory die including a second physical layer, the second physical layer configured to perform input and output of data to and from the processor, the second physical layer not interfering with the first physical layer in a plan view.

In accordance with another embodiment of the inventive concepts, a system-in-package includes an interposer including a first plurality of paths and a second plurality of paths, the interposer including a top surface and a bottom surface, a processor die at a first side of the interposer, the processor die attached to one of the top surface or the bottom surface of the interposer at the first side of the interposer, the processor connected to both the first plurality of paths and the second plurality of paths, a first memory die at a second side of the interposer, the second side opposite to the first side, the first memory die attached to the top surface of the interposer, the first memory die including a first physical layer connected to the first plurality of paths, and a second memory die at the second side of the interposer, the second memory die attached to the bottom surface of the interposer, the second memory die including a second physical layer connected to the second plurality of paths, the second plurality of paths not overlapping the first plurality of paths in a plan view.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a view illustrating a memory device according to an embodiment of the inventive concepts;

FIG. 2 is a view illustrating a lower surface of the first memory die of FIG. 1 and a lower surface of the second memory die of FIG. 1;

FIG. 3 is a view illustrating a section of the memory device taken along III-III′ line of FIG. 1;

FIG. 4 is a view illustrating a memory device according to an example embodiment of the inventive concepts;

FIG. 5 is a view illustrating a memory device according to an example embodiment of the inventive concepts;

FIG. 6 is a view illustrating a lower surface of the first memory die of FIG. 5 and a lower surface of the second memory die of FIG. 5;

FIG. 7 is a view illustrating a section of the memory device taken along line VII-VII′ of FIG. 5;

FIG. 8 is a view illustrating a memory device according to an example embodiment of the inventive concepts;

FIG. 9 is a view illustrating a section of the memory device taken along line IX-IX′ of FIG. 8;

FIG. 10 is a view illustrating a section of the memory device taken along line X-X′ of FIG. 8;

FIG. 11 is a view illustrating a system-in-package according to an example embodiment of the inventive concepts;

FIG. 12 is a view illustrating a system-in-package according to an example embodiment of the inventive concepts;

FIG. 13 is a view illustrating a section of the system-in-package taken along line XIII-XIII′ of FIG. 12;

FIG. 14 is a view illustrating a section of the system-in-package taken along line XIV-XIV′ of FIG. 12; and

FIG. 15 is a view illustrating a system-in-package according to an example embodiment of the inventive concepts.

### DETAILED DESCRIPTION

Hereinafter, some example embodiments of the inventive concepts will be described in detail so that those skilled in the art to which the inventive concepts pertain can easily carry out the inventive concepts.

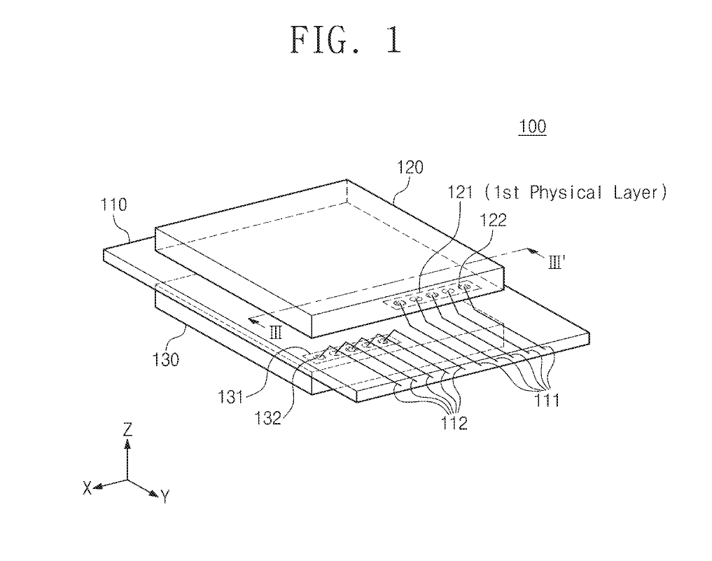

FIG. 1 is a view illustrating a memory device according to an example embodiment of the inventive concepts. Referring to FIG. 1, the memory device 100 may include an interposer 110, a first memory die 120, and a second memory die 130.

The interposer 110 may include a first plurality of paths 111 and a second plurality of paths 112. Through the first plurality of paths 111, data may be written in the first memory die 120 or data may be read from the first memory die 120. Through the second plurality of paths 112, data may be written in the second memory die 130 or data may be read from the second memory die 130. The first plurality of paths 111 and the second plurality of paths 112 may be formed of a metal. For example, the metal may be copper. The numbers of the first plurality of paths 111 and the second plurality of paths 112 are not limited to those illustrated in FIG. 1.

Referring to FIG. 1, the first plurality of paths 111 and the second plurality of paths 112 do not interfere with each other, and a first physical layer (PHY) 121 and a second physical layer (PHY) 131 do not interfere with each other. Here, the expression “not interfere with each other” includes the cases where the first plurality of paths 111 and the second plurality of paths 112 do not overlap each other in a plan view. Further, the expression “not interfere with each other” includes the cases where the first plurality of paths 111 and the second plurality of paths 112 (or the first physical layer 121 and the second physical layer 131) do not vertically overlap each other (e.g., do not overlap each other when viewed from above). In consideration of the locations of the first plurality of paths 111 and the second plurality of paths 112, the locations of the first physical layer 121 of the first memory die 120 and the second physical layer 131 of the second memory die 130 may be set.

The interposer 110 may include an insulating material. For example, the insulating material may be germanium, silicon-germanium, gallium-arsenide (GaAs), glass, ceramic, or the like. Referring to FIG. 1, the first plurality of paths 111 and the second plurality of paths 112 may be covered by an insulating material.

Although not illustrated, the interposer 110 may further include paths that transfers electric power to the first memory die 120 and the second memory die 130. Further, the interposer 110 may further include paths for testing the first memory die 120 and the second memory die 130. The interposer 110 may connect the first memory die 120 and the second memory die 130 to a printed circuit board (PCB) (not illustrated).

The first memory die 120 may be attached to an upper surface (a first surface) of the interposer 110. The first memory die 120 may include a first physical layer 121. The first physical layer 121 may refer an area in which a first plurality of input/output pads 122 are arranged. The first physical layer 121 may be connected to the first plurality of paths 111.

The second memory die 130 may be attached to a lower surface (a second surface') of the interposer 110. The second memory die 130 may be manufactured separately from the first memory die 120. However, the second memory die 130 may be the same as the first memory die 120 for high productivity. In this case, the first memory die 120 may be attached to the upper surface of the interposer 110, and the first memory die 120 may be attached to the lower surface of the interposer 110 after being overturned.

The second memory die 130 may include a second physical layer 131. The second physical layer 131 may refer o an area in which a second plurality of input/output pads 132 are arranged. The second physical layer 131 may be connected to the second plurality of paths 112.

In a plan view (e.g., when viewed from the Z axis direction), the first physical layer 121 and the second physical layer 131 do not interfere with each other (e.g., do not overlap each other). In some example embodiments, the first plurality of input/output pads 122 and the second plurality of input/output pads 132 do not interfere with each other (e.g., do not overlap each other). Accordingly, even though the plurality of memory dies 120 and 130 are attached to both the upper and lower surfaces of the interposer 110, the total number of the first plurality of paths 111 and the second plurality of paths 112 need not be increased. At the same time, the first plurality of paths 111 and the second plurality of paths 112 also do not interfere with each other do not vertically overlap each other).

In general, the total number of the first plurality of paths 111 and the second plurality of paths 112 may be determined by the rules or specifications. For example, the number of the plurality of paths in the interposer 110 may 1024. In a conventional memory device, memory dies are attached only on one surface of the interposer 110. Accordingly, the number of the plurality of input/output pads in the above-mentioned memory dies may be 1024. When the above-mentioned memory dies are attached to both the upper and lower surfaces of the interposer 110, the number of the plurality of paths need to be increased to 2048.

In the memory device 100 according to the example embodiment of the inventive concepts, the first physical layer 121 and the second physical layer 131 do not interfere with (e.g., do not vertically overlap) each other. For example, the number of the first plurality of input/output pads 122 of the first physical layer 121 may be 512. The number of the second plurality of input/output pads 132 of the second physical layer 131 may be 512. Accordingly, the total number of the first plurality of paths 111 and the second plurality of paths 112 is 1024, and thus the number of the plurality of paths need not be increased.

Although not illustrated, the first memory die 120 may include a first memory cell array. For example, the memory cell may include any one of a dynamic random access memory (DRAM), a static random access memory (SRAM), a NAND flash memory, a NOR flash memory, a ferroelectric random access memory (FRAM), a phase change random access memory (PRAM), a thyristor random access memory (TRAM), and a magnetic random access memory (MRAM).

Although not illustrated, the first memory die 120 may include a first test circuit for testing the first memory cell array, a first power source circuit for supplying electric power to the first memory cell array, and/or a first input/output circuit through which data is written in the first memory cell array or is read from the first memory cell. The first memory die 120 may perform the functions of a core die and a buffer die at the same time. Here, the core die may refer to a die including a memory cell array. The buffer die may refer to a die including read circuits and write circuits for accessing a memory cell array of a core die. The above description also may be applied to the second memory die 130 in the same way. That is, the second memory die 130 also may include the second memory cell array. The second memory die 130 may include a second test circuit for testing the second memory cell array, a second power source circuit for supplying electric power to the second memory cell array, or a second input/output circuit through which data is written in the second memory cell array or is read from the second memory cell.

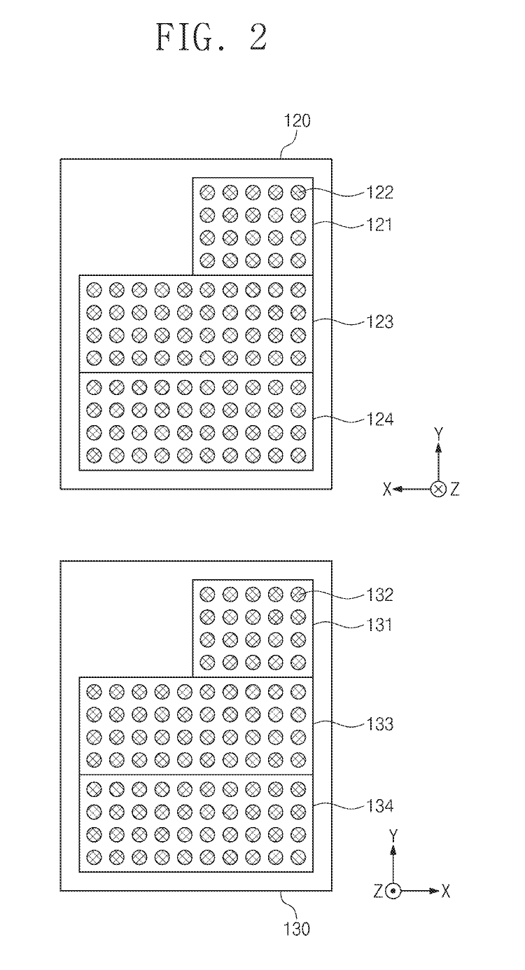

FIG. 2 is a view illustrating a lower surface of the first memory die of FIG. 1 and a lower surface of the second memory die of FIG. 1. FIG. 2 will be described with reference to FIG. 1. Referring to FIG. 2, a first physical layer 121, a first power supply layer 123, and a first test layer 124 may be arranged on the lower surface of the first memory die 120. A second physical layer 131, a second power supply layer 133, and a second test layer 134 may be arranged on the lower surface of the second memory die 130. As described above, the second memory die 130 may be the same as the first memory die 120. Accordingly, the lower surface of the first memory die 120 may be the lower surface of the second memory die 130.

The first physical layer 121 may include a first plurality of input/output pads 122 The first plurality of input/output pads 122 gray be used to write data in a memory cell array in the memory die 120 or read data from the memory cell array. The first memory die 120 may include a plurality of memory cells, and may include a first plurality of input/output pads 122 to process data of the plurality of memory cells at once. The number of the first plurality of input/output pads 122 is not limited to that of FIG. 2. The configuration and operation of the second physical layer 131 is the same as or similar to those of the first physical layer 121. A detailed description of the second physical layer 131 will be omitted.

Referring to FIG. 2, the first physical layer 121 may be arranged on one side of the first memory die 120 based on the center of the first memory die 120, the second physical layer 131 also may be arranged on one side of the second memory die 130 based on the center of the second memory die 130. For example, FIG. 2 illustrates that the first physical layer 121 and the second physical layer 131 are arranged on the right sides of the centers of the memory dies. However, the arrangement (layout) of the first physical layer 121 and the arrangement (layout) of the second physical layer 131 are not limited to those of FIG. 2..

When the first memory die 120 and the second memory die 130 are attached to the interposer 110 as in FIG. 1, the first physical layer 121 and the second physical layer 131 do not interfere with (e.g., do not overlap) each other when the memory device 100 is viewed on a plane (e.g, when viewed from above).

The first power supply layer 123 may include a plurality of power supply pads. Through the plurality of power supply pads, electric power may be supplied to the first memory die 120. The number of the plurality of power supply pads is not limited to that of FIG. 2. The configuration and operation of the second power supply layer 133 is the same as or similar to those of the first power supply layer 123. Accordingly, a detailed description of the second power supply layer 133 will be omitted.

The first test layer 124 may include a plurality of test pads. Through the plurality of test pads, a test may be performed on the first memory die 120. The number of the plurality. of test pads is not limited to that of FIG. 2. The configuration and operation of the second test layer 134 is the same as or similar to those of the first test layer 124. Accordingly, a detailed. description of the second test layer 134 will be omitted.

In some example embodiments, the locations of the first power supply layer 123 and the first test layer 124 may be exchanged. In some example embodiments, the locations of the second power supply layer 133 and the second test layer 134 also may be exchanged.

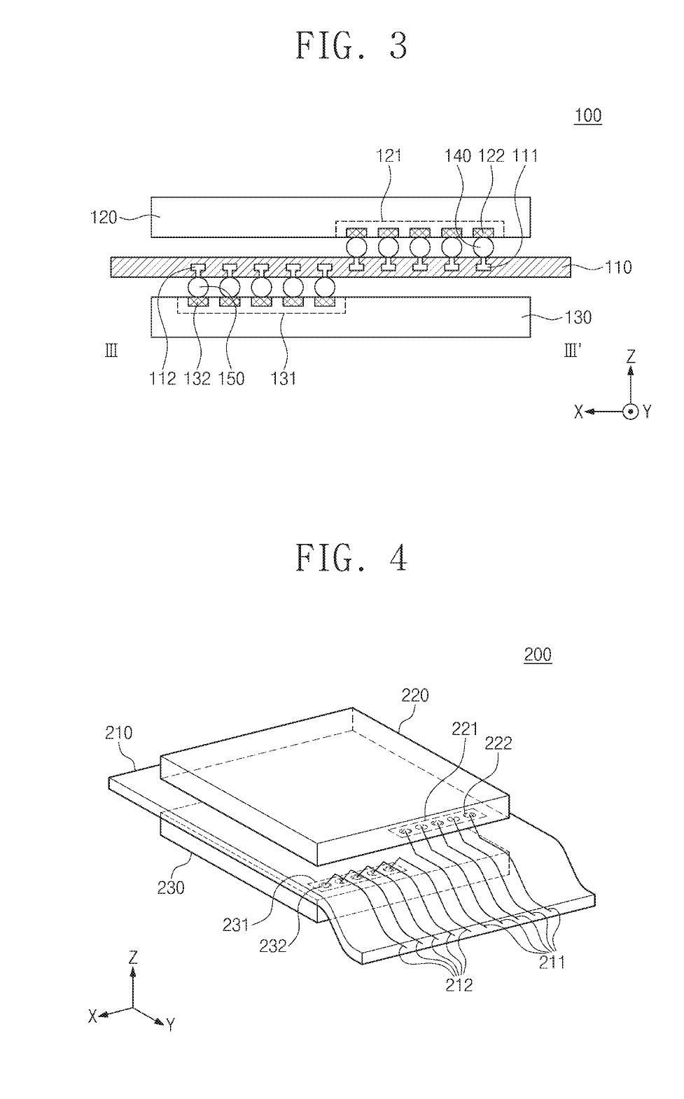

FIG. 3 is a view illustrating a section of the memory device taken along line III-III′ of FIG. 1. FIG. 3 will be described with reference to FIGS. 1 and 2.

Referring to FIG. 3, the memory device 100 may include an interposer 110, a first memory die 120, a second memory die 130, a first plurality of micro-bumps 140, and a second plurality of micro-bumps 150. The interposer 110, the first memory die 120, and the second memory die 130 are the same as those of FIG. 1.

The first plurality of micro-bumps 140 may be arranged between the interposer 110 and the first memory die 120. For example, the first plurality of micro-bumps 140 may be connected to a first plurality of paths 111 of the interposer 110. The first plurality of micro-bumps 140 may be connected to the first physical layer 121 of the first memory die 120. The first plurality of micro-bumps 140 may have, for example, a hemispherical or convex shape. The first plurality of micro-bumps 140 may include Ni, Au, Cu, or an alloy of tin and lead. (Sn—Pb). The sizes of the first plurality of micro-bumps 140 may be several micrometers or several tens of micrometers.

The second plurality of micro-bumps 150 may be arranged between the interposer 110 and the second memory die 130, For example, the second plurality of micro-bumps 150 may be connected to a second plurality of paths 112 of the interposer 110. The second plurality of micro-bumps 150 may be connected to the second physical layer 131 of the second memory die 130. Except for the arrangement locations thereof, the configuration and arrangement of the second plurality of micro-bumps 150 are the same as or similar to those of the first plurality of micro-bumps 140. Accordingly, a detailed description of the second micro-bumps 150 will be omitted.

The interposer 110 may include a first plurality of paths 111 and a second plurality of paths 112, The first plurality of paths 111 may be connected to the upper surface of the interposer 110. For example, the first plurality of paths 111 may be connected to the first plurality of micro-bumps 140. The second plurality of paths 112 may be connected to the lower surface of the interposer 110. The first memory die 120 may include a first physical layer 121. For example, the second plurality of paths 112 may be connected to the second plurality of micro-bumps 150. The second memory die 130 may include a second physical layer 131. The first plurality of micro-bumps 140 may be arranged between the first physical layer 121 and the first plurality of paths 111. The second plurality of micro-bumps 150 may be arranged between the second physical layer 131 and the second plurality of paths 112.

Referring to FIG. 3, when the memory device 100 is viewed from above, the first plurality of paths 111 and the second plurality of paths 112 do not interfere with (e.g., do not vertically overlap) each other. The first physical layer 121 and the second physical layer 131 do not interfere with (e.g., do not vertically overlap) each other. The first plurality of micro-bumps 140 and the second plurality of micro-bumps 150 also do not interfere with (e.g., do not vertically overlap) each other. Further, the first physical layer 121 and the second physical layer 131 are not situated on the same plane. The first plurality of micro-bumps 140 and the second plurality of micro-bumps 150 also are not situated on the same plane.

FIG. 4 is a view illustrating a memory device according to an example embodiment of the inventive concepts. Referring to FIG. 4, the memory device 200 may include an interposer 210, a first memory die 220, and a second memory die 230. The first memory die 220 and the second memory die 230 are the same as those of FIG. 1.

According to this example embodiment, the interposer 210 may have flexibility. For example, the interposer 210 may be manufactured of an insulating material having flexibility. For example, the interposer 210 may be formed of a plastic film (e.g., a polyester film or a polyimide film). In this case, the interposer 210 may be a film interposer. An entire area of the interposer 210 may be implemented by using the above-described insulating material having flexibility. Referring to the example embodiment illustrated in FIG. 4, the interposer 210 may be implemented by using the above-described insulating material having flexibility at a portion thereof (e.g., a curved portion thereof).

The interposer 210 may include a first plurality of paths 211 and a second plurality of paths 212. In response to the curved portion of the interposer 210, the first plurality of paths 211 and the second plurality of paths 212 also may be curved.

Through the flexible interposer 210, the memory device 200 may be connected to the outside regardless of the height thereof. Here, the outside may be an application processor (AP), a substrate, a PCB, or another memory device.

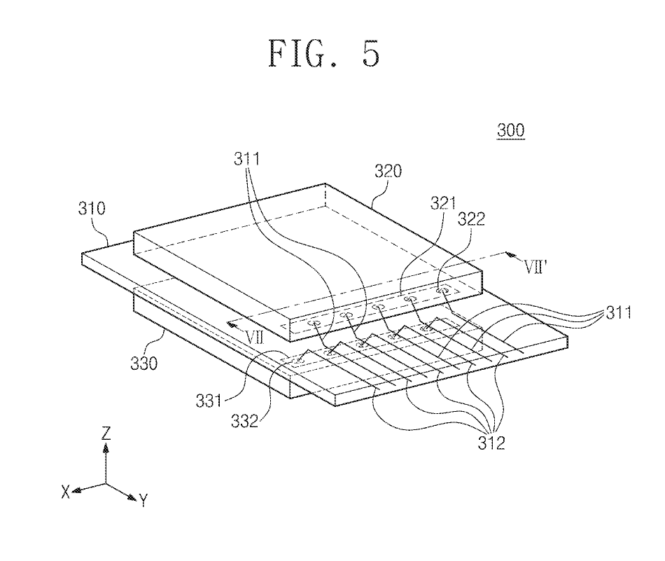

FIG. 5 is a view illustrating a memory device according to an example embodiment of the inventive concepts. FIG. 5 will be described with reference to FIG. 1. Referring to FIG. 5, the memory device 300 may include an interposer 310, a first memory die 320, and a second memory die 330. The interposer 310, the first memory die 320, and the second memory die 330 are the same as or similar to those of FIG. 1.

As being compared with the first plurality of paths 111 and the second plurality of paths 112 of FIG. 1, the first plurality of paths 311 and the second plurality of paths 312 may be arranged in a different way. Referring to FIG. 5, the first plurality of paths 311 and the second plurality of paths 312 may be alternately arranged when viewed from above. Even in this arrangement, the first plurality of paths 311 and the second plurality of paths 312 do not interfere with (e.g., do not vertically overlap) each other.

The first physical layer 321 and the second physical layer 331 may be arranged in consideration of the arrangements of the first plurality of paths 311 and the second plurality of paths 312. Referring to FIG. 5, when the memory device 300 is viewed from above, the first physical layer 321 and the second physical layer 331 may overlap each other. Nevertheless, the first physical layer 321 and the second physical layer 331 may be provided to not interfere with (e.g., to not vertically overlap) each other.

For example, the first physical layer 321 may refer to an area in which a first plurality of input/output pads 322 are arranged, and the second physical layer 331 may refer to an area in which a second plurality of input/output pads 332 are arranged. The first plurality of input/output pads 322 and the second plurality of input/output pads 332 may be alternately arranged when viewed from above. Accordingly, the first physical layer 321 and the second physical layer 331 do not interfere with (e.g., do not vertically overlap) each other.

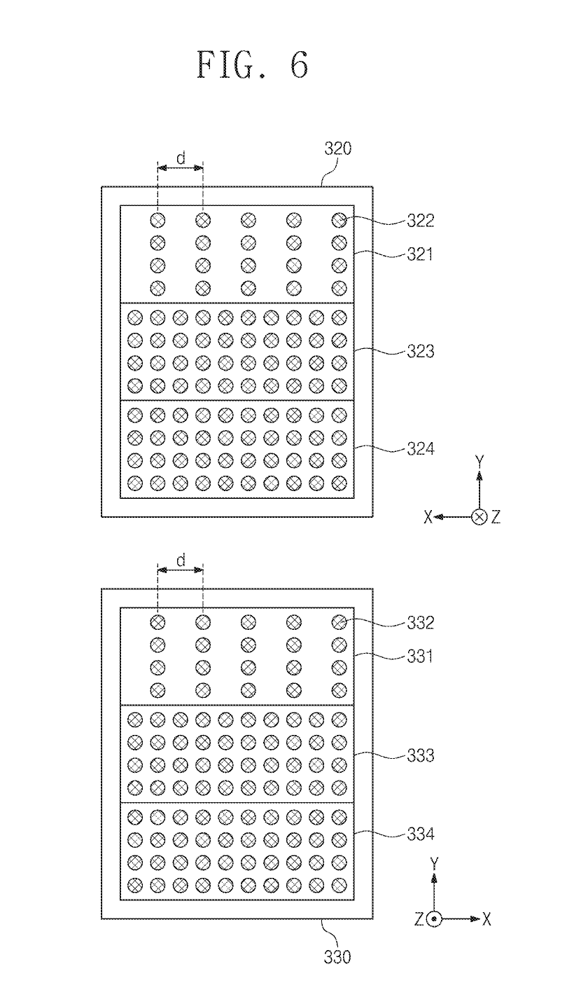

FIG. 6 is a view illustrating a lower surface of the first memory die of FIG. 5 and a lower surface of the second memory die of FIG. 5. FIG. 6 will be described with reference to FIG. 5. Referring to FIG. 6, a first physical layer 321, a first power supply layer 323, and a first test layer 324 may be arranged on the lower surface of the first memory die 320. A second physical layer 331, a second power supply layer 333, and a second test layer 334 may be arranged on the lower surface of the second memory die 330. The first physical layer 321, the first power supply layer 323, the first test layer 324, the second physical layer 331, the second power supply layer 333, and the second test layer 334 are the same as or similar to those of FIG. 2.

The first physical layer 321 may include a first plurality of input/output pads 322 Referring to FIG. 6, the first plurality of input/output pads 322 may be arranged in the first physical layer 321 in columns, and the columns may be spaced apart from each other by a specific distance d, the second plurality of input/output pads 332 may be arranged in the second physical layer 331 in columns, and the columns may be spaced apart from each other by a specific distance d. When the first memory die 320 and the second memory die 330 are attached to the interposer 310, the second plurality of input/output pads 332 may be arranged between the first plurality of input/output pads 322 when viewed from above. Thus, the first plurality of input/output pads 322 and the second plurality of input/output pads 332 do not interfere with (e.g., do not vertically overlap) each other.

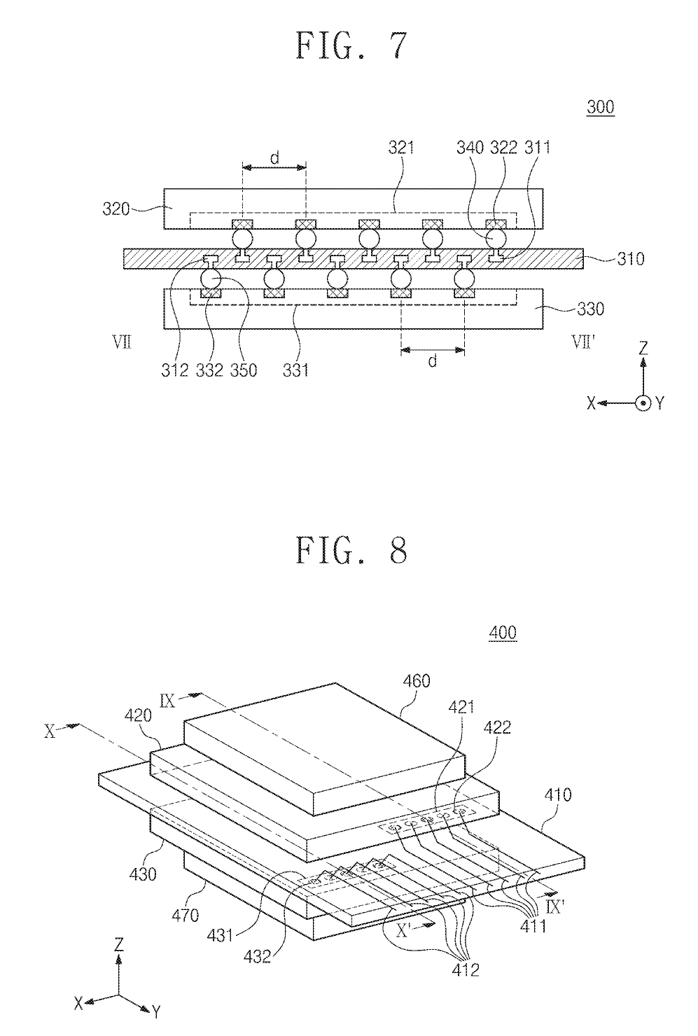

FIG. 7 is a view illustrating a section of the memory device taken along line VII-VII′ of FIG. 5. FIG. 7 will be described with reference to FIGS. 5 and 6.

Referring to FIG. 7, the memory device 300 may include the interposer 310, the first memory die 320, the second memory die 330, a first plurality of micro-bumps 340, and a second plurality of micro-bumps 350. The interposer 310, the first memory die 320, the second memory die 330, the first plurality of micro-bumps 340, and the second plurality of micro-bumps 350 are the same as or similar to those of FIG. 3.

Referring to FIG. 7, when the memory device 300 is viewed on a plane (e.g., viewed from above), the first plurality of paths 311 and the second plurality of paths 312 do not interfere with (e.g. do not overlap) each other. the first plurality of input/output pads 322 and the second plurality of input/output pads 332 do not interfere with (e.g. do not vertically overlap) each other. The first plurality of micro-bumps 340 and the second plurality of micro-bumps 350 also do not interfere with (e.g. do not vertically overlap) each other.

The first plurality of paths 311 may be connected to the first physical layer 321. The second plurality of paths 312 may be connected to the second physical layer 331. Referring to FIG. 7, the first plurality of paths 311 and the second plurality of paths 312 may be alternately arranged one by one in a plan view. The inventive concepts are not limited to the arrangement of FIG. 7, and one or more of the first plurality of paths 311 and one or more of the second plurality of paths 312 may be alternately arranged in a plan view.

FIG. 8 is a view illustrating a memory device according to an example embodiment of the inventive concepts. Referring to FIG. 8, the memory device 400 may include the interposer 410, the first memory die 420, the second memory die 430, a third memory die 460, and a fourth memory die 470. The interposer 410, the first memory die 420, and the second memory die 430 are the same as or similar to those of FIG. 1.

The first memory die 420 may include a first physical layer 421, and the second memory die 430 may include a second physical layer 431.

Referring to FIG. 8, the third memory die 460 may be stacked on the first memory die 420. The fourth memory die 470 may be stacked on the second memory die 430. As the plurality of memory dies are stacked, the total capacity of the memory device 400 may increase. The number of the stacked memory dies is not limited to that of FIG. 8.

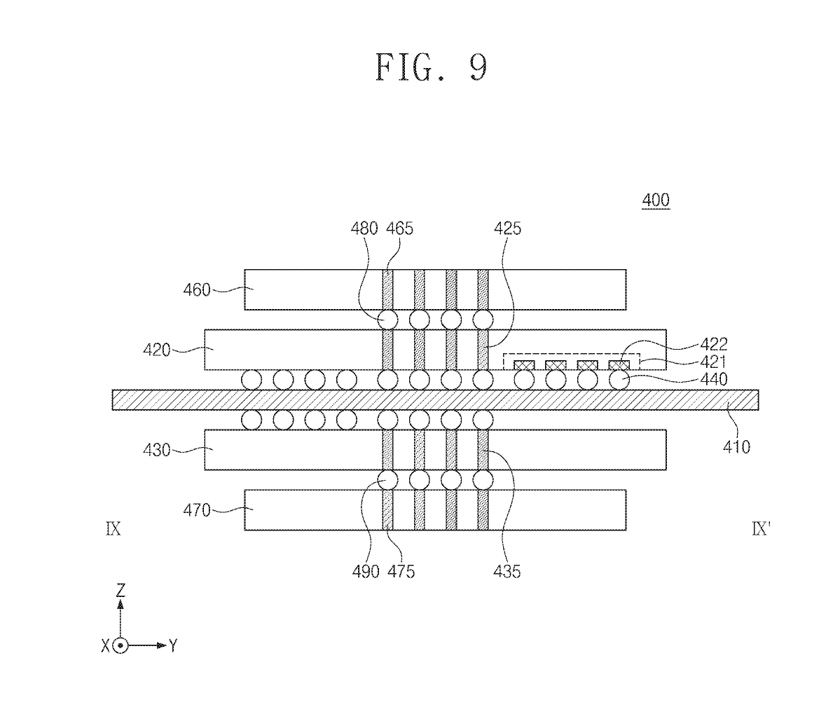

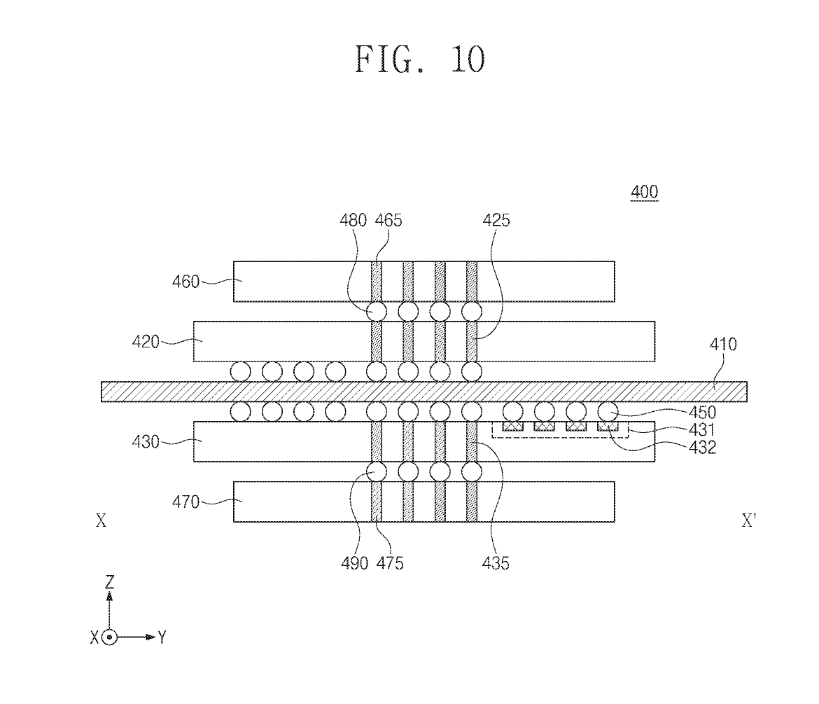

FIG. 9 is a view illustrating a section of the memory device taken along line IX-IX′ of FIG. 8. FIG. 10 is a view illustrating a section of the memory device taken along line X-X′ of FIG. 8. FIG. 9 will be described with reference to FIG. 8.

Referring to FIGS. 9 and 10, the memory device 400 may include an interposer 410, a first memory die 420, a second memory die 430, a first plurality of micro-bumps 440, a second plurality of micro-bumps 450, a third memory die 460, a fourth memory die 470, a third plurality of micro-bumps 480, and a fourth plurality of micro-bumps 490. The interposer 410, the first memory die 420, and the second memory die 430 are the same as or similar to those of FIG. 1. The first plurality of micro-bumps 440 and the second plurality of micro-bumps 450 are the same as or similar to those of FIG. 3.

As described above, the first physical layer 421 and the second physical layer 431 do not interfere with (e.g., do not overlap) each other when viewed from above. For example, the first physical layer 421 and the second physical layer 431 may be arranged on the same side of the corresponding memory dies with respect to the center of the corresponding memory dies. Accordingly, the second plurality of micro-bumps 450 connected to the second physical layer 431 are not illustrated in the section (FIG. 9) of the memory device 400 taken along line IX-IX′. Likewise, the first plurality of micro-bumps 440 connected to the first physical layer 421 are not illustrated in the section (FIG. 10) of the memory device 400 taken along line X-X′.

The first memory die 420 may include a first plurality of through silicon vias (TSVs) 425. Through the first plurality of TSVs 425, the third memory die 460 may be stacked on the first memory die 420. The first memory die 420 may be electrically connected to the third memory die 460 through the first plurality of TSVs 425. Through stacking, the total capacity of the memory device 400 may increase. The third plurality of micro-bumps 480 may be arranged between the first memory die 42.0 and the third memory die 460. The third plurality of micro-bumps 480 may have a configuration that is the same as or similar to that of the first plurality of micro-bumps 440.

The second memory die 430 may include a second plurality of TSVs 435. Through the second plurality of TSVs 435, the fourth memory die 470 may be stacked on the second memory die 430. The second memory die 430 may be electrically connected to the fourth memory die 470 through the second plurality of TSVs 435. Through stacking, the total capacity of the memory device 400 may increase. The fourth plurality of micro-bumps 490 may be arranged between the second memory die 430 and the fourth memory die 470, The fourth plurality of micro-bumps 490 may have a configuration that is the same as or similar to that of the third plurality of micro-bumps 480.

Although not illustrated, a plurality of memory dies may be further stacked on the third memory die 460., a plurality of memory dies also may be further stacked on the fourth memory die 470. Further, the third memory die 460 may include a third plurality of TSVs 465. The fourth memory die 470 may include a fourth plurality of TSVs 475.

In the example embodiment of the inventive concepts, all of the first memory die 420, the second memory die 430, the third memory die 460, and the fourth memory die 470 may be implemented in the same way.

in another example embodiment of the inventive concepts, the first memory die 420 and the second memory die 430 may be implemented in the same way. The third memory die 460 and the fourth memory die 470 may be implemented in the same way. As described above, each of the first memory die 420 and the second memory die 430 may include a test circuit for testing a memory cell array, a power supply circuit for supplying electric power to the memory cell array, and an input/output circuit through which data is written in the memory cell array or data is read from the memory cell array. The first memory die 420 and the second memory die 430 may perform the functions of a core die and a buffer die at the same time.

Unlike the first memory die 420 and the second memory die 430, the third memory die 460 and the fourth memory die 470 may include a memory cell array to perform only the function of a core die. In this case, the areas of the third memory die 460 and the fourth memory die 470 may be smaller than the areas of the first memory die 420 and the second memory die 430.

When the third memory die 460 and the fourth memory die 470 operate as core dies, the test circuits of the first memory die 420 and the second memory die 430 may test the memory cell arrays of the third memory die 460 and the fourth memory die 470. Further, the memory cell arrays of the third memory die 460 and the fourth memory die 470 may be accessed through the input/output circuits of the first memory die 420 and the second memory die 430.

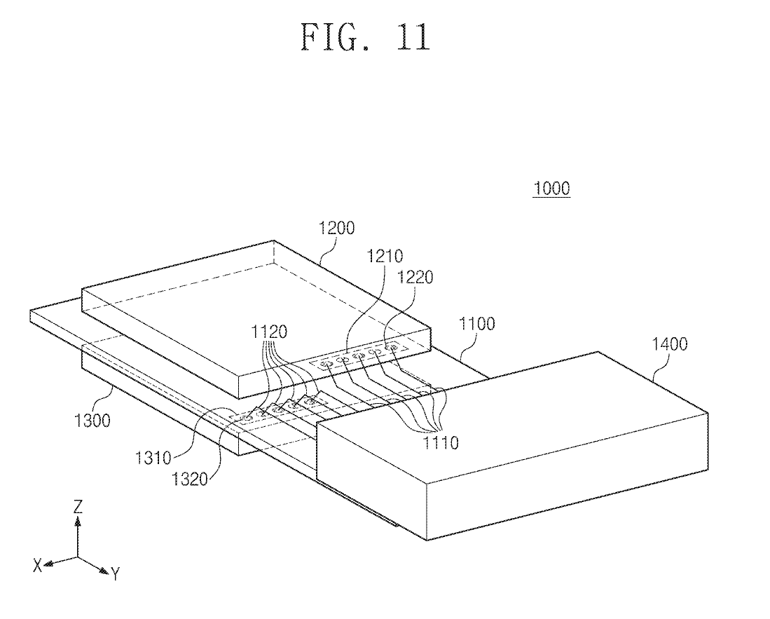

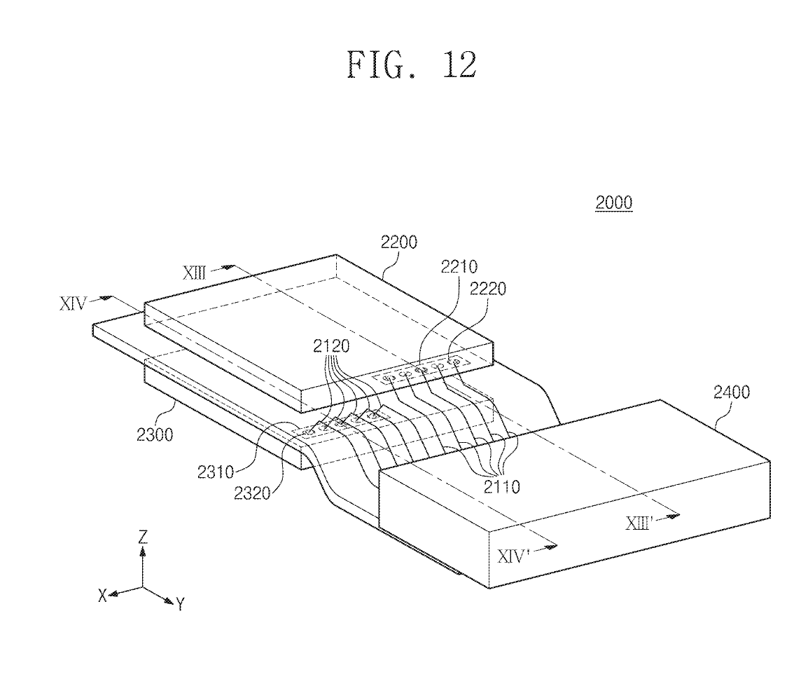

FIG. 11 is a view illustrating a system-in-package according to an example embodiment of the inventive concepts. Referring to FIG. 11, the system-in-package 1000 may include an interposer 1100, a first memory die 1200, a second memory die 1300, and a processor 1400. The interposer 1100 may include a first plurality of paths 1110 and a second plurality of paths 1120. The first memory die 1200 may include a first physical layer 1210. The second memory die 1300 may include a second physical layer 1310. The interposer 1100, the first memory die 1200, the second memory die 1300, the first plurality of paths 1110, the second plurality of paths 1120, the first physical layer 1210, and the second physical layer 1310 are the same as or similar to those of FIG. 1.

The processor 1400 may be connected to the first memory die 1200 and the second memory die 1300 through the interposer 1100. In some example embodiment of the inventive concepts, the processor 1400 may be any one of a central processing unit (CPU), a graphics processing unit (GPU), or a system on chip (SoC). The processor 1400 may perform the function of a host. The processor 1400 may transmit and receive data to and from the first memory die 1200 and the second memory die 1300 through a first plurality of paths 1110 and a second plurality of paths 1120 of the interposer 1100 at a high speed.

A structure in the plurality of memory dies 1200 and 1300 and the processor 1400 are stacked on the interposer 1100 as in FIG. 11 is referred to as 2.5D stacking structure. Although not illustrated, when the plurality of memory dies 1200 and 1300 are stacked on the processor 1400 without using an interposer 1100, the stacking structure may be a 3D stacking structure. As compared with the 3D stacking structure, TSVs for connecting the plurality of memory dies 1200 and 1300 to the processor 1400 may not he desired in the 2.5D stacking structure. Further, the heat generated by the processor 1400 may not be transferred to the plurality of memory dies 1200 and 1300 in the 2.5D stacking structure.

In the system-in-package 1000 according to the embodiment of the inventive concepts, the plurality of memory dies 1200 and 1300 are attached to both the upper and lower surfaces of the interposer 1100. Through this, the capacity of the system-in-package 1000 may increase. Further, the first physical layer 1210 and the second physical layer 1220 do not interfere with each other. Even though the plurality of memory dies 1200 and 1300 are attached to both the upper and lower surfaces of the interposer 1100, the number of the plurality of paths 1110 and 1120 of the interposer 1100 may not increase.

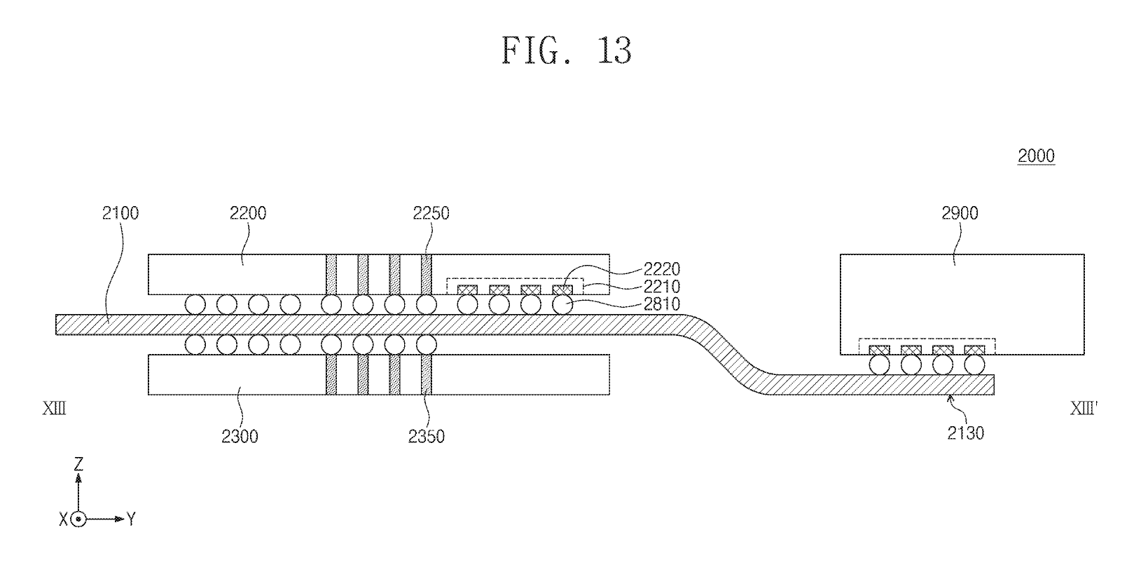

FIG. 12 is a view illustrating a system-in-package according to an example embodiment of the inventive concepts. Referring to FIG. 12, the system-in-package 2000 may include an interposer 2100, a first memory die 2200, a second memory die 2300, and a processor 2400. The interposer 2100 may include a first plurality of paths 2110 and a second plurality of paths 2120. The first memory die 2200 may include a first physical layer 2210. The second memory die 2300 may include a second physical layer 2310.

The interposer 2100, the first memory die 2200, the second memory die 2300, the first plurality of paths 2110, the second plurality of paths 2120, the first physical layer 2210, the second physical layer 2310, and the processor 2400 are the same as or similar to those of FIG. 11. Meanwhile, unlike in FIG. 11, the interposer 2100 may have flexibility in FIG. 12. The flexibility of the interposer 2100 is the same as that of FIG. 4.

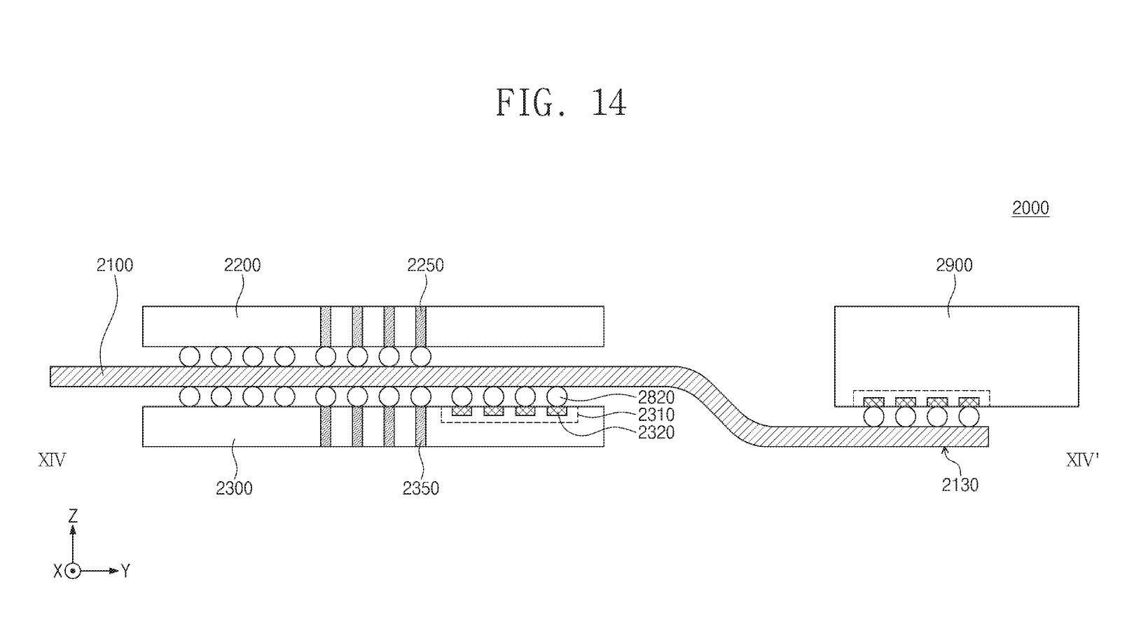

FIG. 13 is a view illustrating a section of the system-in-package taken along line XIII-XIII′ of FIG. 12. FIG. 14 is a view illustrating a section of the system-in-package taken along line XIV-XIV′ of FIG. 12. FIGS. 13 and 14 will be described with reference to FIG. 12. FIG. 13 is a cross-section of the system-in-package 2000 of FIG. 12 taken along the Y axis direction (e.g., an alternate long and short dash line XIII-XIII′). FIG. 14 is a cross-section of the system-in-package 2000 of FIG. 12 taken along the Y axis direction (e.g., an alternate long and short dash line XIV-XIV′).

Referring to FIGS. 13 and 14, the system-in-package 2000 may include an interposer 2100, a first memory die 2200, a second memory die 2300, first and second. pluralities of micro-bumps 2810 and 2820, and a processor 2900. The interposer 2100 may include a first plurality of paths 2110 and a second plurality of paths 2120. The first memory die 2200 may include a first physical layer 2210. The second memory die 2300 may include a second physical layer 2310.

The interposer 2100, the first memory die 2200, the second memory die 2300, the first and second pluralities of micro-bumps 2801 and 2820, and the processor 2900 are the same as or similar to those of FIGS. 8 to 11.

Referring to FIG. 13, the interposer 2100 may be flexible interposer. Through the flexible interposer 2100, a bottom surface of the second memory die 2300 and a bottom surface 2130 of the interposer may be positioned on the same plane. However, a curving degree of the flexible interposer 2100 is not limited to that of FIG. 13.

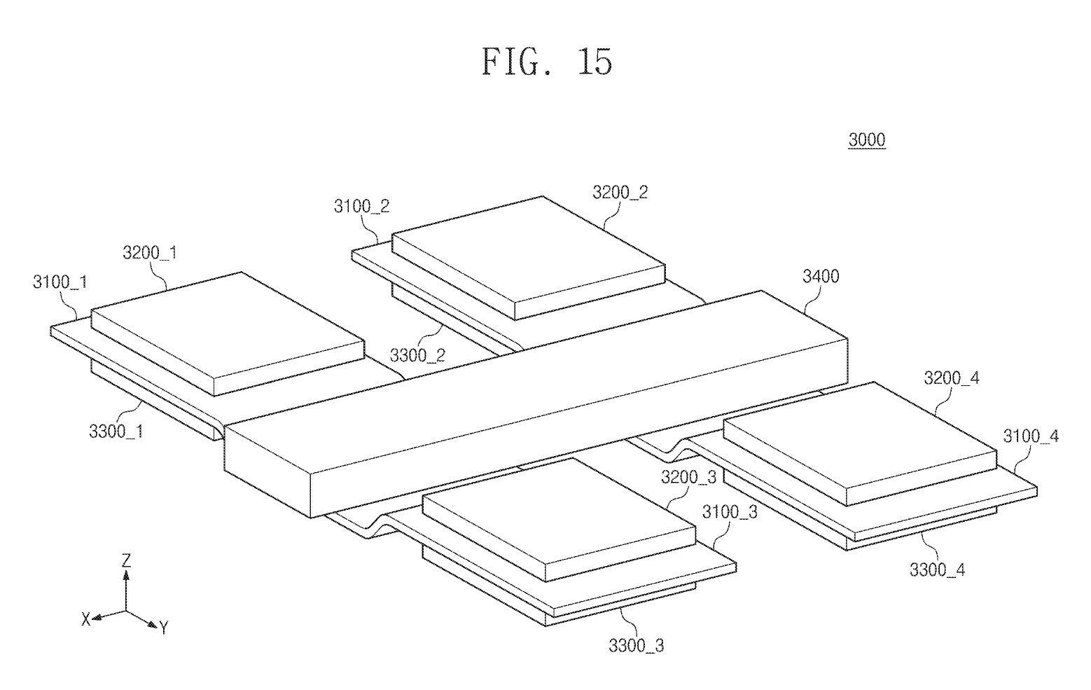

FIG. 15 is a view illustrating a system-in-package according to an example embodiment of the inventive concepts. Referring to FIG. 15, the system-in-package 3000 may include a plurality of interposers 3100_1 to 3100_4, a plurality of memory dies 3200_1 to 3200_4 and 3300_1 to 3300_4, and a processor 3400, The plurality of interposers 3100_1 to 3100_4, the plurality of memory dies 3200_1 to 3200_4 and 3300_4 to 3300_4, and the processor 3400 may be the same as or similar to those of FIGS. 11 to 14. Referring to FIG. 15, the processor 3400 may be coupled to the plurality of interposers 3100_1 to 3100_4 in a transverse direction. Meanwhile, the inventive concepts are not limited thereto, and the processor 3400 may be coupled to the plurality of interposers in a longitudinal direction.

The memory device according to example embodiments of the inventive concepts may increase the capacity of a memory by attaching memory dies to the upper or lower surface of an interposer. The system-in-package according to example embodiments of the inventive concepts may increase the capacity of a memory by attaching memory dies to the upper or lower surface of an interposer.

The above-described contents are detailed examples for carrying out the inventive concepts. The inventive concepts include the above-described embodiments as well as some example embodiments that may be simply modified or easily changed from the above-described example embodiments. Further, the inventive concepts may include the technologies that may be modified by using the above-described example embodiments.

What is claimed is:

1. A memory device comprising:
an interposer including a first plurality of paths and a second plurality of paths;
a first memory die attached to a first surface of the interposer, the first memory die including a first physical layer connected to the first plurality of paths, the first physical layer being attached to the first surface of the interposer; and
a second memory die attached to a second surface of the interposer, the second memory die including a second physical layer connected to the second plurality of paths, the second physical layer being attached to the second surface of the interposer, the second physical layer not interfering with the first physical layer in a plan view. The memory device of claim 1, wherein the first physical layer and the second physical layer have a same layout.

3. The memory device of claim 1, wherein the first plurality of paths and the second plurality of paths do not interfere with each other in the plan view.

4. The memory device of claim 3, wherein the first physical layer and the second physical layer are situated on different planes.

5. The memory device of claim 4, further comprising:
a first plurality of micro-bumps between the first plurality of paths and the first physical layer; and
a second plurality of micro-bumps between the second plurality of paths and the second physical layer,
wherein the first plurality of micro-bumps and the second plurality of micro-bumps do not interfere with each other in the plan view.

6. The memory device of claim 5, wherein the first plurality of micro-bumps and the second plurality of micro-bumps are situated on different planes.

7. The memory device of claim 1, wherein
the first memory die further includes,
a first memory cell array; and
a first test circuit configured to test the first memory cell array, and
the second memory die further includes,
a second memory cell array; and
a second test circuit configured to test the second memory cell array.

8. The memory device of claim 7, wherein
the first memory die further includes a first plurality of through silicon vias (TSVs),
the second memory die further includes a second plurality of TSVs, and
the memory device further includes,
a third memory die electrically connected to the first plurality of TSVs, and
a fourth memory die electrically connected to the second plurality of TSVs.

9. The memory device of claim 8, wherein
the third memory die includes a third memory cell array,
the fourth memory die includes a fourth memory cell array,
the first test circuit is further configured to test at least one of the first memory cell array or the third memory cell array, and
the second test circuit is further configured to test at least one of the second memory cell array or the fourth memory cell array.

10. A system-in-package comprising:
a processor;
an interposer connected to the processor;
a first memory die attached to a first surface of the interposer, the first memory die including a first physical layer, the first physical layer configured to perform input and output of data to and from the processor; and
a second memory die attached to a second surface of the interposer, the second memory die including a second physical layer, the second physical layer configured to perform input and output of data to and from the processor, the second physical layer not interfering with the first physical layer in a plan view.

11. The system-in-package of claim 10, wherein the first physical layer and the second physical layer have a same layout.

12. The system-in-package of claim 10, wherein the interposer comprises:
a first plurality of paths connecting the processor to the first memory die; and
a second plurality of paths connecting the processor to the second memory die, and
wherein the first plurality of paths and the second plurality of paths do not interfere with each other in the plan view.

13. The system-in-package of claim 12, further comprising:
a first plurality of micro-bumps between the first plurality of paths and the first physical layer; and
a second plurality of micro-bumps between the second plurality of paths and the second physical layer,
wherein the first plurality of micro-bumps and the second plurality of micro-bumps do not interfere with each other in the plan view.

14. The system-in-package of claim 13, wherein
the first physical layer and the second physical layer are situated on different planes, and
the first plurality of micro-bumps and the second plurality of micro-bumps are situated on different planes.

15. The system-in-package of claim 10, wherein
first memory die includes a first plurality of through silicon vias (TSVs),
the second memory die further includes a second plurality of TSVs, and
the system-in-package further comprises a third memory die and a fourth die, the third memory die electrically connected to the first plurality of TSVs, and the fourth memory die electrically connected to the second plurality of TSVs,

16. A system-in-package comprising:
an interposer including a first plurality of paths and a second plurality of paths, the interposer including a top surface and a bottom surface;
a processor die at a first side of the interposer, the processor die attached to one of the top surface or the bottom surface of the interposer at the first side of the interposer, the processor connected to both the first plurality of paths and the second plurality of paths;
a first memory die at a second side of the interposer, the second side opposite to the first side, the first memory die attached to the top surface of the interposer, the first memory die including a first physical layer connected to the first plurality of paths; and
a second memory die at the second side of the interposer, the second memory die attached to the bottom surface of the interposer, the second memory die including a second physical layer connected to the second plurality of paths, the second plurality of paths not overlapping the first plurality of paths in a plan view.

17. The system-in-package of claim 16, wherein the first physical layer do not overlap the second physical layer in the plan view.

18. The system-in-package of claim 16, wherein the first physical layer includes a first plurality of input/output pads, and the second physical layer includes a second plurality of input/output pads.

19. The system-in-package of claim 18, wherein the first plurality of input/output pads and the second plurality of input/output pads are alternately arranged in the plan view.

20. The system-in-package of claim 16, wherein at least a portion of the interposer includes a flexible material.
